(19) United States
(12) Patent Application Publication
(10) Pub. No.: US 2024/0008324 A1
(43) Pub. Date: Jan. 4, 2024

(54) DISPLAY PANEL AND DISPLAY APPARATUS

(71) Applicant: Hubei Yangtze Industrial Innovation Center Of Advanced Display Co., Ltd., Wuhan (CN)

(72) Inventor: Weiqiang YANG, Wuhan (CN)

(73) Assignee: Hubei Yangtze Industrial Innovation Center Of Advanced Display Co., Ltd., Wuhan (CN)

(21) Appl. No.: 17/971,661

(22) Filed: Oct. 24, 2022

(30) Foreign Application Priority Data
Jun. 30, 2022 (CN) 202210760689.2

(51) Int. Cl. H01L 27/32

(52) U.S. Cl. CPC H01L 27/3276

(57) ABSTRACT

The present application discloses a display panel and a display device. The display panel includes a display area and a non-display area. The display area includes a first functional area and a second functional area surrounded by the first functional area. A light transmittance of the second functional area is higher than a light transmittance of the first functional area. The non-display area is located on one side of the first functional area away from the second functional area. The non-display area comprises a first sub-edge and a second sub-edge which form an edge of the display panel. A distance from the first sub-edge to the first functional area is smaller than a distance from the second sub-edge to the first functional area, and the first sub-edge is arranged closer to the second functional area than the second sub-edge.

### CROSS REFERENCE TO RELATED APPLICATION

This application claims priority to Chinese Patent Application No. 202210760689.2, filed on Jun. 30, 2022, which is hereby incorporated by reference in its entirety.

### TECHNICAL FIELD

The present application relates to a field of display technology, and particularly to a display panel and a display apparatus.

### BACKGROUND

An overall size and weight of a display panel are important considerations when applying the display panel in a display apparatus. In order to make the appearance of the electronic device more beautiful and the screen display area larger, it is required to narrow the frame size of the display panel as much as possible, i.e., the so called narrow frame. Currently, the present technology may achieve the purpose of reducing the size of the frame area of the flexible display panel by bending the non-display area of the base substrate in the flexible display panel to the backlight side of the display panel.

The display panel is provided with area with high light transmittance such as under-screen camera area, fingerprint recognition area or the like. After the non-display area is bent, it is likely to block the area with high light transmittance and reduce the light transmittance.

### SUMMARY

The object of the present application is to provide a display panel and a display apparatus.

A first aspect of the present application provides a display panel including a display area and a non-display area. The display area includes a first functional area and a second functional area surrounded by the first functional area, a light transmittance of the second functional area is higher than a light transmittance of the first functional area. The non-display area is located on one side of the first functional area away from the second functional area, the non-display area comprises a first sub-edge and a second sub-edge which form an edge of the display panel, a distance from the first sub-edge to the first functional area is smaller than a distance from the second sub-edge to the first functional area, and the first sub-edge is arranged closer to the second functional area than the second sub-edge.

A second aspect of the present application provides a display apparatus including the display panel described above.

### BRIEF DESCRIPTION OF THE DRAWINGS

In order to explain the technical solutions of the embodiments of the present application more clearly, the following briefly introduces the drawings that need to be used in the embodiments of the present application. Obviously, the drawings described below are only some embodiments of the present application. For those ordinary skilled in the art, other drawings may further be obtained from these drawings without the exercise of inventive faculty.

FIG. 1 is a schematic diagram of a display panel in a flattened state provided by an embodiment of the present application;

FIG. 2 is a schematic diagram of another display panel in a flattened state provided by an embodiment of the present application;

FIG. 3 is a schematic cross-sectional structure diagram of a display panel provided by an embodiment of the present application;

FIG. 4 is a schematic diagram of a display panel in a bent state provided by an embodiment of the present application;

FIG. 5 is a schematic diagram viewing from another angle of the display panel in a bent state provided by an embodiment of the present application;

FIG. 6 is a schematic diagram of yet another display panel in a flattened state provided by an embodiment of the present application;

FIG. 7 is a partial schematic diagram of a display panel provided by an embodiment of the present application;

FIG. 8 is another partial schematic diagram of a display panel provided by an embodiment of the present application;

FIG. 9 is a partial schematic diagram of a display panel provided by an embodiment of the present application;

FIG. 10 is another partial schematic diagram of a display panel provided by an embodiment of the present application;

FIG. 11 is another partial schematic diagram of a display panel provided by an embodiment of the present application;

FIG. 12 is a partial schematic diagram of a display panel provided by an embodiment of the present application;

FIG. 13 is another partial schematic diagram of a display panel provided by an embodiment of the present application;

FIG. 14 is a partial schematic diagram of a display panel provided by an embodiment of the present application;

FIG. 15 is another partial schematic diagram of a display panel provided by an embodiment of the present application;

FIG. 16 is a partial schematic diagram of a display panel provided by an embodiment of the present application;

FIG. 17 is yet another partial schematic diagram of a display panel provided by an embodiment of the present application;

FIG. 18 is yet another partial schematic diagram of a display panel provided by an embodiment of the present application;

FIG. 19 is yet another partial schematic diagram of a display panel provided by an embodiment of the present application;

FIG. 20 is a schematic diagram of a display panel provided by an embodiment of the present application;

FIG. 21 is another schematic diagram of a display panel provided by an embodiment of the present application; and

FIG. 22 is yet another partial schematic diagram of a display panel provided by an embodiment of the present application.

The reference numbers are as follows:

Display area AA; first functional area 11; second functional area 12; first edge 1a; second edge 1b; first end 121; second end 122; third end 123; fourth end 124; non-display area NA; first sub-non-display area 21; second sub-non-display area 22; third sub-non-display area 23; fourth sub-non-display area 24; fifth sub-non-display area 25; first sub-edge 2a, second sub-edge 2b; third sub-edge 2c; fourth sub-edge 2d; first sub-bend area 26; second sub-bend area 27; binding area 28; crease 261; third edge 2e; fourth edge 2f; step 29; chip binding area 281; FPC binding area 282; first direction X; second direction Y; first chip 31; second chip 32; signal line 40; data signal line 41; first power signal line 42; second power signal line 43; FPC 50; bending area 60; light emitting side 71; backlight side 72; array substrate 81; substrate 811; array layer 812; light emitting device layer 82; encapsulation layer 83; and light emitting unit 821.

### DETAILED DESCRIPTION

The embodiments of the present application will be described in further detail below with reference to the accompanying drawings and examples. The following detailed description of the embodiments and the accompanying drawings are intended to illustrate the principles of the present application by way of example, but not to limit the scope of the present application, that is, the present application is not limited to the described embodiments.

In the description of this application, it should be noted that, unless otherwise specified, the “plurality” means two or more; the terms “upper”, “lower”, “left”, “right”, “inside”, “outside” and the like indicate an orientation or positional relationship which is only for the convenience of describing the present application and simplifying the description, rather than indicating or implying that the indicated device or element must have a specific orientation, be constructed and operated in a specific orientation, and therefore should not be considered as a limitation to the present application. In addition, the terms “first”, “second”, “third” and the like are used for descriptive purposes only and should not be considered as indicating or implying relative importance. “Vertical” is not strictly vertical, but within the allowable range of errors. “Parallel” is not strictly parallel, but within the allowable range of errors.

Reference in this application to “an embodiment” means that a particular feature, structure, or characteristic described in connection with the embodiment may be included in at least one embodiment of the application. The appearances of the phrase in various positions in the description are not necessarily all referring to the same embodiment, nor a separate or alternative embodiment that is mutually exclusive with other embodiments. It is explicitly and implicitly understood by those skilled in the art that the embodiments described in this application may be combined with other embodiments.

Orientation words appearing in the following description are all directions shown in the drawings, and do not limit the specific structure of the present application. In the description of this application, it should also be noted that, unless otherwise expressly specified and limited, the terms “installed”, “coupled” and “connected” should be understood in a broad sense, for example, there may be a fixed connection or a detachable connection; or a direct connection or an indirectly connection via an intermediate medium. For those ordinary skilled in the art, the specific meanings of the above terms in the present application may be understood according to specific circumstances.

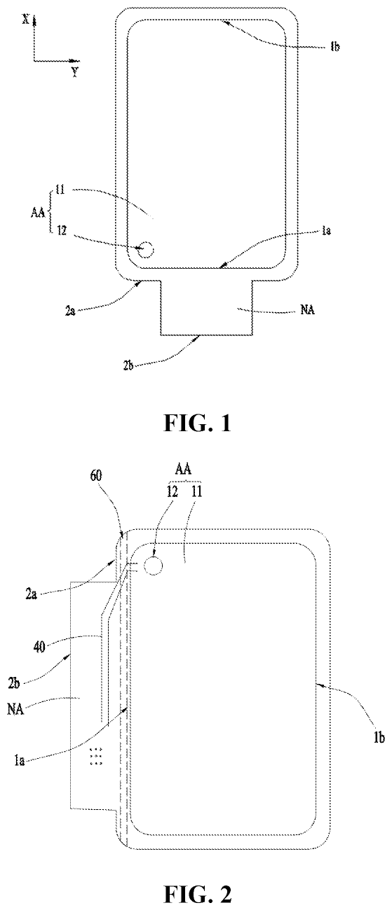

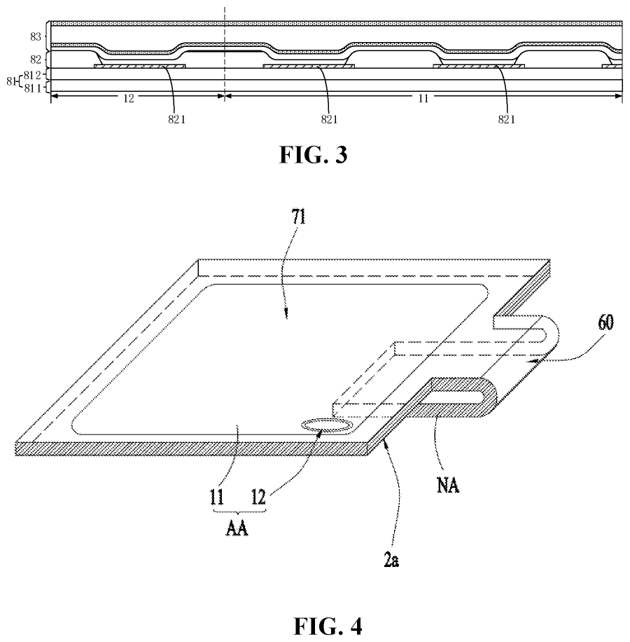

As shown in FIG. 1, FIG. 2 and FIG. 3, FIG. 1 is a schematic diagram of a display panel in a flattened state provided by an embodiment of the present application, and FIG. 2 is a schematic diagram of another display panel in a flattened state provided by an embodiment of the present application. FIG. 3 is a schematic cross-sectional structure diagram of a display panel provided by an embodiment of the present application.

The display panel includes a display area AA and a non-display area NA. The display area AA refers to an area which may display images and is provided with pixel units; and the non-display area NA refers to an area which cannot display images, which is generally used for arranging lines or placing bound terminals, test terminals, VSR circuits or the like.

Optionally, the non-display area NA may surround the display area AA along the circumference of the display area AA, or may be arranged on any side or opposite sides of the display area AA, for example, the non-display area may be arranged at the bottom or side of the display panel. It should be noted that the bottom of the display panel refers to the area where chips are arranged and the lines are connected to the chips; and the side of the display panel refers to the line area on the left or right of the frame of the display panel.

The display panel includes an array substrate 81, a light emitting device layer 82 and an encapsulation layer 83 which are stacked in sequence. The array substrate 81 includes a substrate 811 and an array layer 812. The substrate 811 may be a flexible substrate 811 made of materials such as polyimide (PI), polyethylene terephthalate (PET) or the like, so that the non-display area NA of the display panel may be bent. A driving circuit for controlling the light emitting device layer 82 to emit light is provided in the array layer 812. The array layer 812 is generally composed of inorganic film layers such as a metal layer, a semiconductor layer (active layer), an insulating layer, and so on. By patterning these inorganic film layers, the driving circuit for controlling the light emitting of the light emitting device layer 82 may be formed. There are various implementation manners for the specific circuit structure, which will not be repeated here.

The light emitting device layer 82 is located on one side of the array layer 812 away from the substrate 811; the light emitting device layer 82 includes an anode layer, a light emitting layer and a cathode layer, and the light emitting layer further includes a light emitting material layer, a hole transport layer and an electron transport layer. When the anode layer and the cathode layer are electrified, electrons and holes migrate from the electron transport layer and the hole transport layer to the light emitting material layer, and meet in the light emitting material layer to form excitons to excite the light emitting molecules, thereby generating visible light to achieve the purpose of display.

The encapsulation layer 83 is located on one side of the light emitting device layer 82 away from the substrate 811, and covers the light emitting device layer 82 to protect the light emitting device layer 82 from being corroded and damaged by water vapor and oxygen. The encapsulation layer 83 may be a thin film encapsulation layer 83, it includes an inorganic encapsulation layer 83, an organic encapsulation layer 83, and an inorganic encapsulation layer 83 which are stacked, to realize the effect of blocking water vapor and oxygen.

The display area AA includes a first functional area 11 and a second functional area 12 surrounded by the first functional area 11. A light transmittance of the second functional area 12 is higher than a light transmittance of the first functional area 11. A light emitting side 71 is a side of the display panel that the light is emitted, and a backlight side 72 is arranged opposite to the light emitting side 71. The light transmittance of the second functional area 12 being higher than the light transmittance of the first functional area 11 may be understood as that the second functional area 12 may enable more external light from the light emitting side 71 to pass through the display panel to be exited from the backlight side 72 than the first functional area 11.

The light emitting device layer includes a plurality of light emitting units 821, and the light emitting units 821 in the second functional area 12 may be distributed sparser than the light emitting units 821 in the first functional area 11, so that the distance between adjacent light emitting units 821 in the second functional area 12 is larger than the distance between adjacent light emitting units 821 in the first functional area 11, for realizing the light transmittance of the second functional area 12 being higher than the light transmittance of the first functional area 11. Alternatively, the size of the light emitting unit in the second functional area 12 is smaller than the size of the light emitting unit in the first functional area 11, so that when the distance between adjacent light emitting units 821 in the second functional area 12 is the same as the distance between adjacent light emitting units 821 in the first functional area 11, the light transmittance of the second functional area 12 being greater than the light transmittance of the first functional area 11 is realized. Compared with the first functional area 11, the side of the second functional area 12 away from the light emitting side 71 of the display panel is more suitable for arranging photosensitive elements such as a camera, an infrared sensor or the like, to sense the light which is from the light emitting side and passes through the display panel and is exited form the backlight side 72. In order to realize the full-screen design of the display apparatus, a light-passing hole may be disposed on the opaque layer of the display panel, and in a direction perpendicular to the substrate, a projection of the light-passing hole and a projection of the photosensitive element overlap with each other. The opaque layer may specifically be an inorganic insulating layer in the array layer 812, or a pixel defining layer located on the array layer 812, or the like.

In other embodiments, a via which runs through the display panel may further be disposed in the second functional area 12, to allow more light to pass through the second functional area 12. In this manner, the second functional area 12 cannot display images.

Optionally, an orthographic projection of the second functional area 12 on the display panel may be in a shape of a circle, an ellipse, a rectangle or other polygons. The second functional area 12 may be arranged on one side of the display area AA near the bottom of the display panel, as shown in the embodiment of FIG. 1; or the second functional area 12 may be arranged on one side of the display area AA near the top of the display panel, as shown in the embodiment of FIG. 2. A bending area 60 is arranged on a side of the display panel, and the non-display area NA is to be bent to the backlight side 72 along this side of the display panel. It should be noted that the top of the display panel refers to the side of the display panel opposite to the bottom.

Optionally, the non-display area NA is located on one side of the first functional area 11 away from the second functional area 12, and the non-display area NA includes a first sub-edge 2a and a second sub-edge 2b that form an edge of the display panel. When the display panel is in a flattened state, a distance from the first sub-edge 2a to the first functional area 11 is smaller than a distance from the second sub-edge 2b to the first functional area 11, and the first sub-edge 2a is arranged closer to the second functional area 12 than the second sub-edge 2b. It should be noted that the first sub-edge 2a and the second sub-edge 2b may be located on a same side of the display panel, or may be located on different sides of the display panel. When the display panel is in the flattened state, the first sub-edge 2a is arranged closer to the second functional area 12 than the second sub-edge 2b, that is, a distance from the first sub-edge 2a to the second functional area 12 is smaller than a distance from the second sub-edge 2b to the second functional area 12.

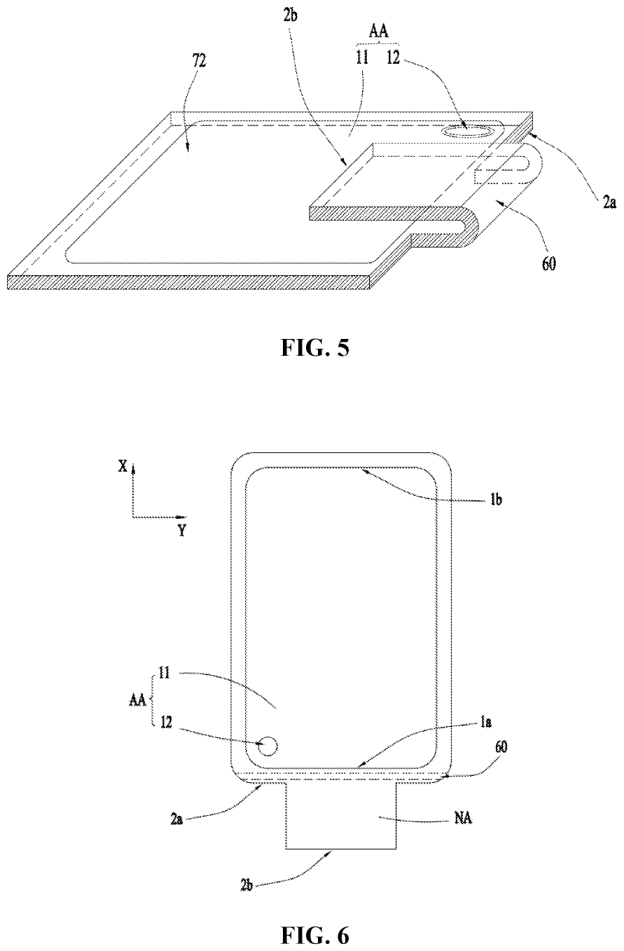

FIG. 4 is a schematic diagram of a display panel in a bent state provided by an embodiment of the present application; and FIG. 5 is a schematic diagram viewing from another angle of the display panel in a bent state provided by an embodiment of the present application.

It should be noted that the flattened state and the bent state described in this application respectively refer to a flattened state and a bent state of the non-display area NA of the display panel. Specifically, as shown in FIG. 4 and FIG. 5, the non-display area of the display panel is bent along the bending area 60, and a part of the non-display area is bent to the backlight side, and the bending direction is an extension direction of the first sub-edge 2a or the second sub-edge 2b. The viewing angle of FIG. 4 is the light emitting side of the display panel, and the viewing angle of FIG. 5 is the backlight side 72 of the display panel. The display panel with a narrow frame may be obtained when the non-display area is bent.

In some embodiments, if the bending area 60 is located in a part of the non-display area corresponding to the second sub-edge 2b, the second sub-edge 2b is bent to the backlight side 72 of the display panel. Since the second sub-edge 2b is farther away from the second functional area 12 than the first sub-edge 2a, the part of the non-display area corresponding to the second sub-edge 2b will not cover the second functional area 12. It is avoided that the part of the non-display area bent to the backlight side 72 of the display panel will block the second functional area 12, and the light transmittance of the second functional area 12 will not be affected. It should be noted that the part of the non-display area corresponding to the second sub-edge 2b refers to a part of the non-display area with the second sub-edge 2b as its edge.

Further, in some other optional embodiments of the present application, as shown in FIG. 6, which is a schematic diagram of yet another display panel in a flattened state provided by an embodiment of the present application, and the bending area is located between the first sub-edge 2a and the display area AA. Since the distance from the first sub-edge 2a to the first functional area 11 is smaller than the distance from the second sub-edge 2b to the first functional area 11, even if both the first sub-edge 2a and the second sub-edge 2b are bent to the backlight side 72 of the display panel, the bent first sub-edge 2a is spaced apart from the edge of the second functional area 12 by a certain distance, or is tangent to the edge of the second functional area 12, and the part of the non-display area NA bent to the backlight side of the display panel will not block the second functional area 12.

In addition, the bending area 60 is arranged between the first sub-edge 2a and the second functional area 12, so that the bending area 60 passes through the parts of the non-display area corresponding to the first sub-edge 2a and the second sub-edge 2b, respectively, and a width of the bending area 60 in the extension direction of the first sub-edge 2a or the second sub-edge 2b is relatively large. Under a condition that the number of signal lines 40 remains unchanged, a line space of the bending area 60 becomes larger, which is benefit to arrange the signal lines 40 in the bending area 60, and may ensure that the signal lines 40 in the bending area 60 will not be restricted.

Optionally, further, a distance from the first sub-edge 2a to the bending area 60 is smaller than a distance from the bending area 60 to the second functional area 12, thereby ensuring that after the non-display area NA is bent, the first sub-edge 2a is spaced apart from the second functional area 12 by a certain distance.

In this embodiment, by arranging the first sub-edge 2a and the second sub-edge 2b in the non-display area NA, and defining the distance from the first sub-edge 2a to the first functional area 11 being smaller than the distance from the second sub-edge 2b to the first functional area 11, and the first sub-edge 2a being arranged closer to the second functional area 12 than the second sub-edge 2b, it is avoided that the bent non-display area NA of the display panel will block the second functional area 12 with a higher light transmittance, and it is avoided that the light transmittance of the second functional area 12 will be affected.

In some embodiments, the display area AA has a first edge 1a and a second edge 1b in a first direction X which are arranged opposite to and spaced apart from each other, and the first edge 1a and the second edge 1b are located on opposite sides of the second functional area 12, respectively. The first edge 1a and the second edge 1b may be arranged in parallel. The first sub-edge 2a and the second sub-edge 2b are located on a same side of the first edge 1a, and both the first sub-edge 2a and the second sub-edge 2b are sub-edges of an area of the non-display areas NA arranged along the first edge 1a.

When the display panel is in the flattened state, the distance from the first sub-edge 2a to the first functional area 11 is smaller than the distance from the second sub-edge 2b to the second functional area 12, and the first sub-edge 2a is closer to the first edge 1a than the second sub-edge 2b. When the display panel is in the bent state after being bent, the first sub-edge 2a is spaced apart from the edge of the second functional area 12 by a certain distance, or is tangent to the edge of the second functional area 12. The distance from the second sub-edge 2b to the second functional area 12 is farther, and the second sub-edge 2b will not cover the second functional area 12, it is avoided that the bent non-display area NA of the display panel will block the second functional area 12 with a higher light transmittance, and it is avoided that the light transmittance of the second functional area 12 will be affected. Further, the first sub-edge 2a and the second sub-edge 2b are located on the same side of the first edge 1a, which may reduce the size of the frame of the display panel and realize a narrow frame design, compared with the scheme that the first sub-edge 2a and the second sub-edge 2b are located on the opposite sides of the first edge 1a.

Further, in some embodiments, the distance from the first edge 1a to the second functional area 12 is smaller than the distance from the second edge 1b to the second functional area 12, that is, the second functional area 12 is arranged closer to the first edge 1a than the second edge 1b. After the non-display area NA on one side of the first edge 1a is bent to the backlight side 72 of the display panel, the second sub-edge 2b is bent to the backlight side 72 of the display panel, or both the first sub-edge 2a and the second sub-edge 2b are bent to the backlight side 72 of the display panel. Since the first sub-edge 2a is closer to the second functional area 12 than the second sub-edge 2b, and the distance from the first sub-edge 2a to the second functional area 12 is smaller than the second sub-edge 2b to the second functional area 12, the parts of the non-display area corresponding to the first sub-edge 2a and the second sub-edge 2b will not block the second functional area 12.

Optionally, the first edge is arranged close to the bottom of the display panel. Since the chip is generally arranged at the bottom of the display panel, if the second functional area 12 is a transparent display area and the second functional area 12 is arranged close to the first edge 1a, the length of a line for connecting a light emitting unit 821 in the second functional area 12 to the chip may be reduced.

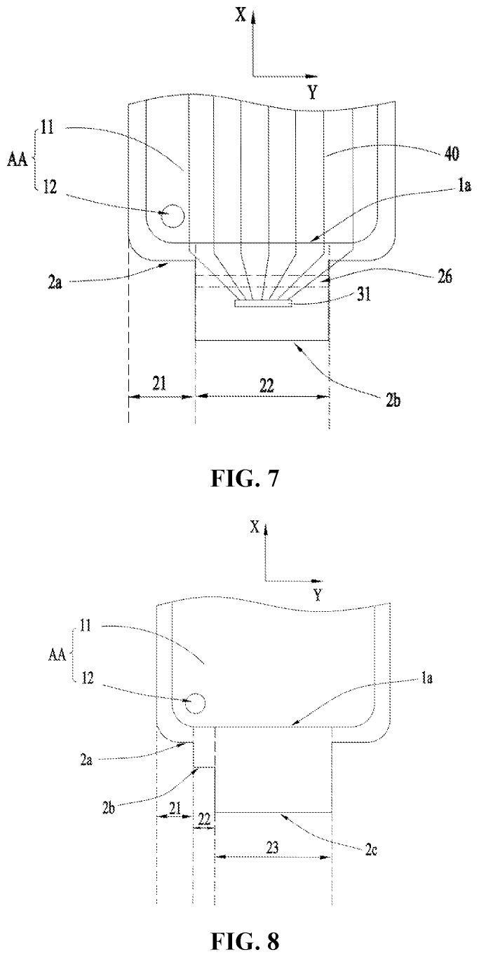

FIG. 7 is a partial schematic diagram of a display panel provided by an embodiment of the present application. In some embodiments, the non-display area NA includes a first sub-non-display area 21 and a second sub-non-display area 22 arranged along the first edge 1a, the first sub-edge 2a is an edge of the first sub-non-display area 21, and the second sub-edge 2b is an edge of the second sub-non-display area 22. The first sub-non-display area 21 and the second sub-non-display area 22 are sequentially arranged in a second direction Y, the second direction Y and the first direction X are perpendicular to each other, and both are parallel to the plane where the display panel is located.

In this embodiment, since the first sub-edge 2a is arranged closer to the second functional area 12 than the second sub-edge 2b, the first sub-edge 2a is the edge of the first sub-non-display area 21, and the second sub-edge 2b is the edge of the second sub-non-display area 22, the first sub-non-display area 21 is arranged closer to the second functional area 12 than the second sub-non-display area 22. If the bending is occurred in first sub-non-display area 21, an orthographic projection of the first sub-non-display area 21 in a direction perpendicular to the display panel substrate 811 will not overlap with the second functional area 12, and the first sub-non-display area 21 will not block the second functional area 12. Since the second sub-non-display area 22 is farther away from the second functional area 12 than the first sub-non-display area 21, an orthographic projection of the second sub-non-display area 22 in the direction perpendicular to the display panel substrate will not overlap with the second functional area 12 either, and the second sub-non-display area 22 will not block the second functional area 12 either. Thus, the light transmittance of the second functional area 12 will not be reduced. It may be understood that, if the bending is occurred in the second sub-non-display area 22, the part of the non-display area bent to the backlight side 72 of the display panel will not block the second functional area 12 either.

Optionally, the first sub-edge 2a and the second sub-edge 2b extend in the second direction Y respectively, and then a width of the first sub-non-display area 21 in the first direction X is smaller than a width of the second sub-non-display area 22 in the first direction X.

In this embodiment, by distributing the first sub-edge 2a and the second sub-edge 2b in two different sub-non-display areas respectively, the bending area may be selected as required, which improves the compatibility of the display panel of the embodiment. If bending is occurred in the first sub-non-display area 21, it may cause the frame of the display panel narrower. If the bending is occurred in the second sub-non-display area 22, and when the edge side of the display area AA that intersects with the first edge 1a is further provided with a sub-non-display area and the sub-non-display area also need to be bent, the intersection corner area (intersection area of different edges of the display panel) may be prevented from being folded-piled up, and wrinkles may be reduced, thereby improving a combined effect of the corner area after bending. It should be noted that the edge side of the display area AA that intersects with the first edge 1a refers to another side edge of the display area AA that intersects with the first edge 1a, for example, sub-non-display areas are arranged not only at the upper and bottom of frame of the display panel area, but also on the left and right sides of the frame of the display panel.

Optionally, the display panel further includes a first chip 31 and a plurality of signal lines 40 extending in the first direction X. Since width of the second sub-non-display area 22 in the first direction X is large, the first chip 31 is arranged in the second sub-non-display area 22, and the signal lines 40 are connected to the first chip 31. For a setting requirement that the second functional area 12 needs to be close to the first edge 1a, in order to make the first sub-non-display area 21 and the second sub-non-display area 22 not block the second functional area 12 after bending, a width of the first sub-non-display area 21 in the second direction Y must be greater than or equal to a width of the second functional area 12 in the second direction Y. Increasing the width of the first sub-non-display area 21 in the second direction Y will reduce the width of the second sub-non-display area 22 in the second direction Y, which results in that not all of the signal lines 40 of the non-display area NA may be able to be arranged, or the fan-out of lines for the corner areas of the display panel may not be realized, or under a condition that the number of the signal lines 40 remains unchanged, the distance between the signal lines 40 needs to be reduced, and the difficulty of the process will be increased.

FIG. 8 is another partial schematic diagram of a display panel provided by an embodiment of the present application. In some embodiments, as shown in FIG. 8, the non-display area NA further includes a third sub-non-display area 23 located on one side of the second sub-non-display area 22 away from the first sub-non-display area 21. The first sub-non-display area 21, the second sub-non-display area 22 and the third sub-non-display area 23 are sequentially arranged along the first edge 1a. The third sub-non-display area 23 includes a third sub-edge 2c forming the edge of the display panel. The distance from the second sub-edge 2b to the first functional area 11 is smaller than a distance from the third sub-edge 2c to the first functional area 11. The width of the second sub-non-display area 22 in the first direction X is smaller than a width of the third sub-non-display area 23 in the first direction X. The second sub-edge 2b is arranged closer to the second functional area 12 than the third sub-edge 2c, that is, the second sub-non-display area 22 is arranged closer to the second functional area 12 than the third sub-non-display area 23.

In this embodiment, after the non-display area NA is bent, the second sub-edge 2b is spaced apart from the edge of the second functional area 12 by a certain distance, or is tangent to the edge of the second functional area 12, the orthographic projection of the second sub-non-display area 22 in the direction perpendicular to the display panel substrate will not overlap with the second functional area 12, so that the second sub-non-display area 22 will not block the second functional area 12. Since the third sub-non-display area 23 is farther away from the second functional area 12 than the second sub-non-display area 22, after the non-display area NA is bent, the orthographic projection of the third sub-non-display area 23 in the direction perpendicular to the display panel substrate will not overlap with the second functional area 12 either, and the third sub-non-display area 23 will not block the second functional area 12 either, which ensures that the light transmittance of the second functional area 12 will not be decreased, and is benefit to the arrangement of the signal lines 40, and ensures that the arrangement of the signal lines 40 will not be restricted.

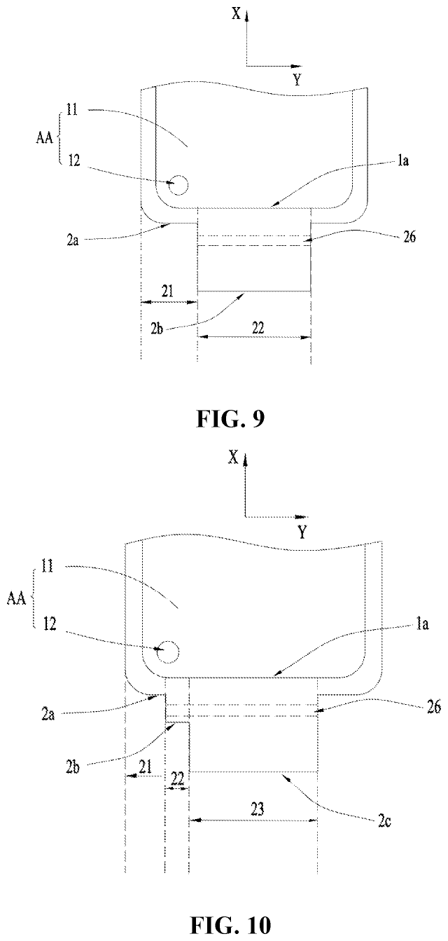

Please refer to FIG. 9 and FIG. 10 in combination, FIG. 9 is a partial schematic diagram of a display panel provided by an embodiment of the present application; and FIG. 10 is another partial schematic diagram of a display panel provided by an embodiment of the present application. In some embodiments, the non-display area NA further includes a first sub-bending area 26, and at least part of the first sub-bending area 26 is located within the area of the second sub non-display area 22.

The crease 261 of the first sub-bending area 26 extends in the second direction Y. If the non-display area NA is only provided with the first sub-non-display area 21 and the second sub-non-display area 22 on the side of the first edge 1a, the whole of first sub-bending area 26 is located within the area of the second sub-non-display area 22. If the non-display area NA is provided with the first sub-non-display area 21, the second sub-non-display area 22 and the third sub-non-display area 23 on the side of the first edge 1a, a part of the first sub-bending area 26 is located within the area of the second sub-non-display area 22, and the other part of the first sub-bending area 26 is located within the area of the third sub-non-display area 23. In other words, the first sub-bending area 26 does not pass through the first sub-non-display area 21. If a sub-non-display area is further provided on an edge side of the display area AA of the display panel which intersects the first edge 1a and the sub-non-display area also needs to be bent, the intersection corner area may be prevented from being folded-piled up, and wrinkles may be reduced, thereby improving a combined effect of the corner area after bending.

In addition, in the embodiment described above, after the third sub-non-display area 23 is added, the first sub-bending area 26 may pass through the second sub-non-display area 22 and the third sub-non-display area 23 in the second direction Y respectively, and the width of the first sub-bending area 26 in the second direction Y is increased, such that under a condition that the number of signal lines 40 remains unchanged, the line space of the first sub-bending area 26 becomes larger, which is benefit to arrange the signal lines in the first sub- bending area 26, and may ensure that the signal lines 40 in the first sub-bending area 26 will not be restricted, compared with the embodiment that only the first sub-non-display area 21 and the second sub-non-display area 22 are arranged in the second direction Y and the first sub-bending area 26 is arranged only in the second sub-non-display area 22 in the second direction Y.

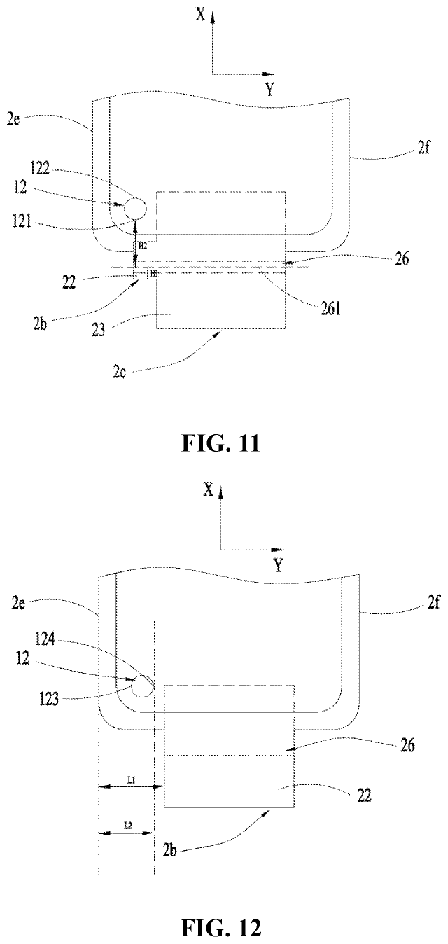

FIG. 11 is another partial schematic diagram of a display panel provided by an embodiment of the present application. In some embodiments, the non-display area NA includes a third edge 2e and a fourth edge 2f arranged opposite to each other in a second direction Y, and the third edge 2e and the fourth edge 2f are edges of the display panel. In this embodiment, the non-display area NA is circumferentially arranged along the circumference of the display area AA. In other embodiments, no non-display area portion may be provided in the second direction Y, and then the third edge 2e and the fourth edge 2f are the edges of the display area AA.

The third edge 2e is arranged close to the second functional area 12, the second functional area 12 is formed with a first end 121 and a second end 122 in the first direction X, and the first end 121 is arranged close to the first edge 1a. In the first direction X, a distance from the second sub-edge 2b to the first sub-bending area 26 is smaller than or equal to a distance from the first sub-bending area 26 to the first end 121.

The first sub-bending area 26 is bent along the crease 261, and the crease 261 extends along the second direction Y. It should be noted that the distance from the second sub-edge 2b to the first sub-bending area 26 in this embodiment refers to a component H1 of a distance from the second sub-edge 2b to the crease 261 in the first direction X, and the distance from the first sub-bending area 26 to the first end 121 refers to a component H2 of a distance from the crease 261 to the first end 121 in the first direction X.

In this embodiment, when the display panel is in the flattened state, H1 [symbol] H2. After the non-display area NA is bent along the crease 261 of the first sub-bending area 26, the second sub-edge 2b will be located on the backlight side 72 of the display panel, and the second sub-edge 2b will be spaced apart from the first end 121 by a certain distance or contacted with the first end 121, and the part of the second sub-non-display area 22 bent to the backlight side 72 of the display panel will not block the second functional area 12.

FIG. 12 is a partial schematic diagram of a display panel provided by an embodiment of the present application. Further, the non-display area NA includes a third edge 2e and a fourth edge 2f arranged opposite to each other in a second direction Y, and the first direction X and the second direction Y are perpendicular to each other. The third edge 2e is arranged close to the second functional area 12, the second functional area 12 is formed with a third end 123 and a fourth end 124 in the second direction Y, and the third end 123 is arranged close to the third edge 2e. In the second direction Y, a distance from the third edge 2e to the second sub-non-display area 22 is greater than or equal to a distance from the third edge 2e to the fourth end 124.

It should be noted that the distance from the third edge 2e to the second sub-non-display area 22 refers to a component L1 of a distance from the third edge 2e to the second sub-non-display area 22 in the second direction Y, and the distance from the third edge 2e to the four ends 124 refers to a component L2 of a distance from the third edge 2e to the fourth end 124 in the second direction Y. When the display panel is in the flattened state, L1 [symbol] L2. When the non-display area NA is bent along the crease 261 of the first sub-bending area 26, one side of the second sub-non-display area 22 close to the third edge 2e will be spaced apart from the fourth end 124 by a certain distance, or contacted with the fourth end 124, which ensures that the second sub-non-display area 22 bent to the backlight side 72 of the display panel will not cover and block the second functional area 12, and the light transmittance of the second functional area 12 will not be affected.

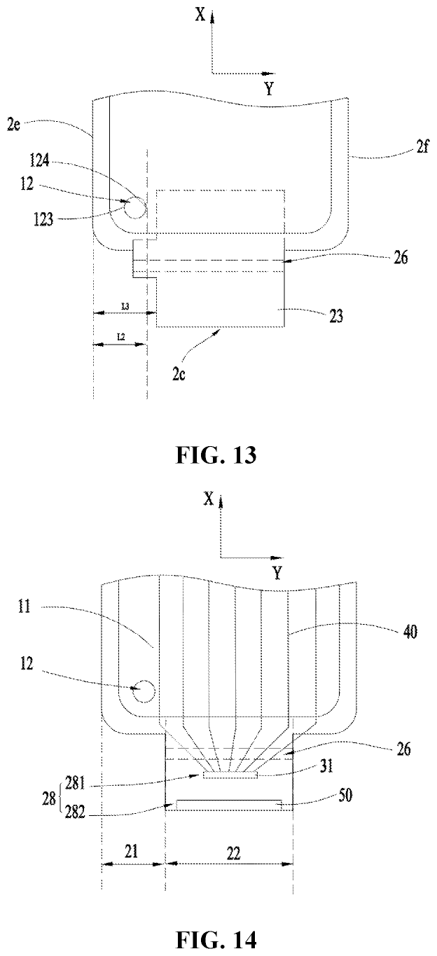

FIG. 13 is another partial schematic diagram of a display panel provided by an embodiment of the present application. In other embodiments, the non-display area NA further includes a third sub-non-display area 23 located on one side of the second sub-non-display area 22 away from the first sub-non-display area 21, the third sub-non-display area 23 includes a third sub-edge 2c forming the edge of the display panel, and the distance from the second sub-edge 2b to the first functional area 11 is smaller than a distance from the third sub-edge 2c to the first functional area 11. The first sub-non-display area 21, the second sub-non-display area 22 and the third sub-non-display area 23 are sequentially arranged along the first edge 1a. The width of the second sub-non-display area 22 in the first direction X is smaller than a width of the third sub-non-display area 23 in the first direction X. In the second direction Y, a distance from the third edge 2e to the third sub-non-display area 23 is greater than or equal to a distance from the third edge 2e to the fourth end 124.

It should be noted that the distance from the third edge 2e to the third sub-non-display area 23 refers to a component L3 from the third edge 2e to the third sub-non-display area 23 in the second direction Y. When the display panel is in the flattened state, L3 [symbol] L2. When the non-display area NA is bent along the crease 261 of the first sub-bending area 26, one side of the third sub-non-display area 23 close to the third edge 2e is spaced apart from the fourth end 124 by a certain distance, or contacted with the fourth end 124, it is avoided that the third sub-non-display area 23 bent to the backlight side 72 of the display panel will cover and block the second functional area 12, and the light transmittance of the second functional area 12 will not be affected.

FIG. 14 is a partial schematic diagram of a display panel provided by an embodiment of the present application. As shown in FIG. 14, in some embodiments, the display panel further includes a first chip 31, an FPC 50 (flexible circuit board), and a plurality of signal lines 40 extending in the first direction X. The first chip 31 and the FPC 50 are arranged in the second sub-non-display area 22. The signal lines 40 are connected to the first chip 31, and the first chip 31 includes a plurality of input pins and a plurality of input pins which are electrically connected to the lines on the FPC 50 respectively. The first chip 31 and the FPC 50 provide driving signals to the pixel array in the display panel to realize image display.

The non-display area NA further includes a binding area 28. The binding area 28 includes a chip binding area 281 and an FPC binding area 282. The first chip 31 is located in the chip binding area 281, and the FPC 50 is located in the FPC binding area 282. Since the width of the second sub-non-display area 22 in the first direction X is large, arranging the binding area 28 in the area of the second sub-non-display area 22 may facilitate the installation of the first chip 31 and the FPC 50.

Optionally, both the first sub-bending area 26 and the binding area 28 are located in the area of the second sub-non-display area 22. When the display panel is in the flattened state, the first sub-bending area 26 is located between the display area AA and the binding area 28. After the display panel is bent along the crease 261 of the first sub-bending area 26, the binding area 28 is located on the backlight side 72 of the display panel, so as to reduce the frame of the display panel and realize a narrow frame design.

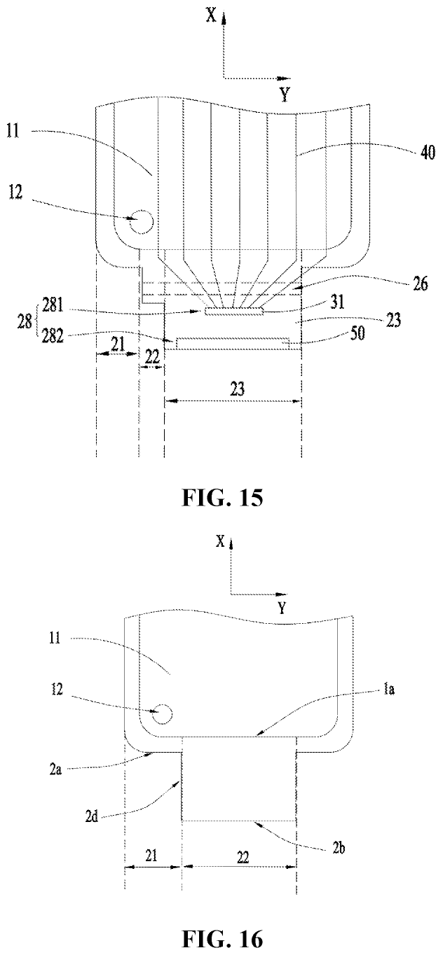

FIG. 15 is another partial schematic diagram of a display panel provided by an embodiment of the present application. In other embodiments, the non-display area NA further includes a third sub-non-display area 23 located on one side of the second sub-non-display area 22 away from the first sub-non-display area 21, and the third sub-non-display area 23 includes a third sub-edge 2c forming the edge of the display panel. The distance from the second sub-edge 2b to the first functional area 11 is smaller than a distance from the third sub-edge 2c to the first functional area 11. The first sub-non-display area 21, the second sub-non-display area 22 and the third sub-non-display area 23 are sequentially arranged along the first edge 1a. The width of the second sub-non-display area 22 in the first direction X is smaller than the width of the third sub-non-display area 23 in the first direction X. The first sub-bending area 26 passes through the second sub-non-display area 22 and the third sub-non-display area 23, and the width of the first sub-bending area 26 in the second direction Y is increased, which may ensure that the signal lines 40 of the first sub-bending area 26 will not be restricted. The binding area 28 is located in the area of the third sub-non-display area 23, and the first sub-bending area 26 is located between the display area AA and the binding area 28.

FIG. 16 is a partial schematic diagram of a display panel provided by an embodiment of the present application. As shown in FIG. 16, in some embodiments, the first sub-edge 2a and the second sub-edge 2b extend in the second direction Y respectively, and the first direction X and the second direction Y are perpendicular to each other.

The first sub-edge 2a and the second sub-edge 2b are arranged in parallel and spaced apart from each other, and both extend in the second direction Y, which facilitates cutting and reduces the difficulty of the manufacturing process. The second sub-non-display area 22 further includes a fourth sub-edge 2d, the first sub-edge 2a and the second sub-edge 2b are connected via the fourth sub-edge 2d, and the fourth sub-edge 2d may be a straight line extending in the first direction X. That is, the fourth sub-edge 2d is perpendicular to the first sub-edge 2a and the second sub-edge 2b respectively, which facilitates cutting and reduces the difficulty of the manufacturing process.

Optionally, the fourth sub-edge 2d may also be inclined with respect to the first direction X, for example, the fourth sub-edge 2d is inclined towards a direction away from the third edge 2e, with respect to the first direction X, which is benefit to fan out lines for the second sub-non-display area 22. In other embodiments, the fourth sub-edge 2d may further have other shapes such as curves, arcs, or the like.

In other embodiments, the first sub-edge 2a and/or the second sub-edge 2b is inclined in a direction away from the first functional area 11, with respect to the second direction Y, and the first direction X and the second direction Y are perpendicular to each other.

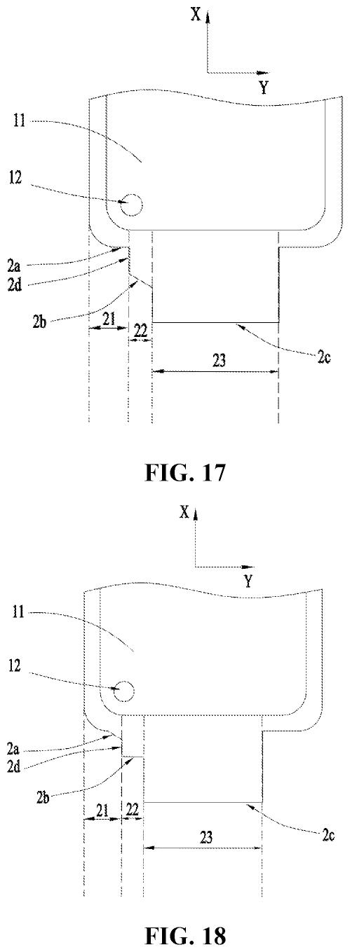

FIG. 17 is yet another partial schematic diagram of a display panel provided by an embodiment of the present application. In the embodiment shown in FIG. 17, the first sub-edge 2a extends in the second direction Y, the second sub-edge 2b is inclined in a direction away from the first functional area 11, with respect to the second direction Y. The second sub-non-display area 22 further includes a fourth sub-edge 2d arranged between the first sub-edge 2a and the second sub-edge 2b, the first sub-edge 2a and the second sub-edge 2b are connected via the fourth sub-edge 2d, and the fourth sub-edge 2d extends in the first direction X. The second sub-edge 2b is inclined towards a direction away from the first functional area 11 from the fourth sub-edge 2d. An end of the first sub-bending area 26 in the second direction Y is connected to the fourth sub-edge 2d. The second sub-edge 2b is located on one side of the first sub-bending area 26 away from the display area AA. Thereby, the lines of the first sub-bending area 26 will not be affected. The inclining setting of the second sub-edge 2b is benefit to fan out lines at the bottom of the first sub-bending area 26. Of course, in other embodiments, the first sub-edge 2a and the second sub-edge 2b may also be directly connected.

FIG. 18 is yet another partial schematic diagram of a display panel provided by an embodiment of the present application. In the embodiment shown in FIG. 18, the first sub-edge 2a is inclined towards a direction away from the first functional area 11, with respect to the second direction Y, and the second sub-edge 2b extends in the second direction Y. The second sub-non-display area 22 further includes a fourth sub-edge 2d arranged between the first sub-edge 2a and the second sub-edge 2b, the first sub-edge 2a and the second sub-edge 2b are connected via the fourth sub-edge 2d, and the fourth sub-edge 2d extends in the first direction X. The first sub-edge 2a is inclined towards a side away from the first functional area 11 in a direction pointed to fourth sub-edge 2d, which is benefit to fan our lines for the corner area of the display panel.

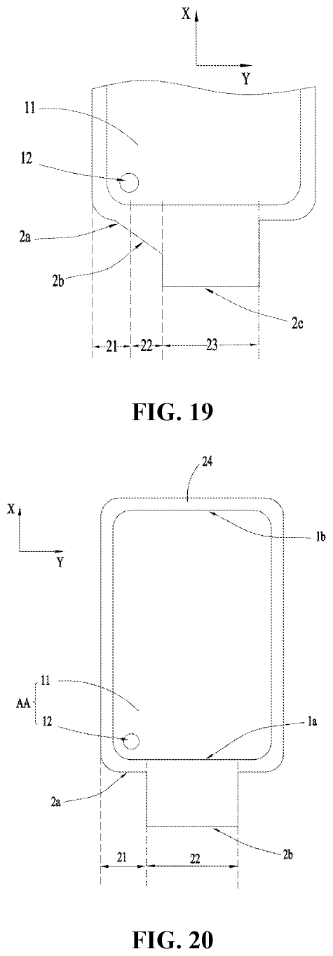

FIG. 19 is yet another partial schematic diagram of a display panel provided by an embodiment of the present application. In the embodiment shown in FIG. 19, both the first sub-edge 2a and the second sub-edge 2b are inclined towards a direction away from the first functional area 11, with respect to the second direction Y, the first sub-edge 2a and the second sub-edge 2b are connected directly, and both are inclined towards a side of the first functional area 11 in a direction from the first sub-edge 2a pointing to the second sub-edge. The slopes of the first sub-edge 2a and the second sub-edge 2b are the same, which increases space for fanning out lines for the corner area. The first sub-bending area 26 is located in the area of the second sub-non-display area 22. Since the shape of the first sub-bending area 26 is a shape with the ends of the first sub-bending area outward, the signal lines 40 of the first sub-bending area 26 may also be arranged following this shape, which is benefit to fan out lines for the first sub-bending area 26. In other embodiments, the slopes of the first sub-edge 2a and the second sub-edge 2b may also be different, or the first sub-edge 2a and the second sub-edge 2b may be indirectly connected.

FIG. 20 is a schematic diagram of a display panel provided by an embodiment of the present application. In some embodiments, the non-display area NA further includes a fourth sub-non-display area 24 located on one side of the second edge 1b, and the first sub-non-display area 21 is arranged closer to the second functional area 12 than the fourth sub-non-display area 24. A portion of the signal lines 40 may be arranged in the fourth sub-non-display area 24, so that the number of signal lines 40 arranged in the second sub-non-display area 22 is reduced. Even if the width of the second sub-non-display area 22 in the second direction Y is reduced in order to avoid blocking the second functional area 12, it may be ensured that the second sub-non-display area 22 has enough space for the lines.

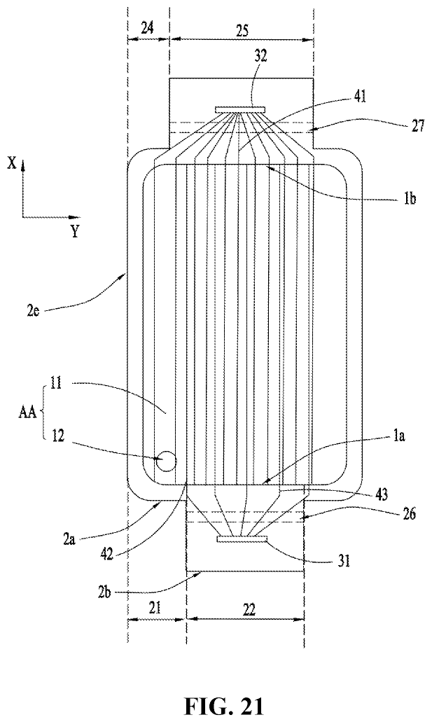

FIG. 21 is another schematic diagram of a display panel provided by an embodiment of the present application. As shown in FIG. 21, the non-display area NA further includes a fifth sub-non-display area 25 located on one side of the second edge 1b, and a width of the fourth sub-non-display area 24 in the first direction X is smaller than a width of the fifth sub-non-display area 25 in the first direction X.

The non-display area NA includes the first sub-bending area 26 and a second sub-bending area 27 extending in the second direction Y, the first sub-bending area 26 is located in the area of the second sub non-display area 22, and the second sub-bending area 27 is located in the area of the fifth sub-non-display area 25. The second sub-non-display area 22 and the fifth sub-non-display area 25 may be bent to the backlight side 72 of the display panel by means of the first sub-bending area 26 and the second sub-bending area 27, respectively. Thereby, the width of the frame of the display panel is reduced, and a narrow frame design is realized.

Optionally, if a sub-non-display area NA is further arranged on an edge side (such as the third edge 2e) that intersects with the first edge 1a or the second edge 1b and the sub-non-display area NA also needs to be bent, by bending in the second sub non-display area 22 and the fifth sub-non-display area 25 respectively, the intersection corner area may be prevented from being folded-piled up, and wrinkles may be reduced, thereby improving a combined effect of the corner area after bending.

In other embodiments, the first sub-bending area 26 may also pass through the first sub-non-display area 21 and the second sub-non-display area 22 respectively, and the second sub-bending area 27 may also pass through the fourth sub-non-display area 24 and the fifth sub-non-display area 25 respectively.

It may be understood that, since the fifth sub-non-display area 25 is located on the side of the second edge 1b and away from the second functional area 12, even if the fifth sub-non-display area 25 is bent, it will not interfere with the second functional area 12. Thus, there is not a limitation on a component of a distance from the third edge 2e to the fifth sub-non-display area 25 in the second direction Y, which may be greater than L1 or smaller than or equal to L1.

In some embodiments, the display panel further includes a first chip 31, a second chip 32 and a plurality of signal lines 40 extending in the first direction X, the first chip 31 is arranged in the second sub-non-display area 22, the second chip 32 is arranged in the fifth sub-non-display area 25, a portion of the signal lines 40 are connected to the first chip 31, and the other portion of the signal lines 40 are connected to the second chip 32.

Since the line space of the second sub-non-display area 22 is larger than that of the first sub-non-display area 21, and the line space of the fifth sub-non-display area 25 is larger than that of the fourth sub-non-display area 24, the first chip 31 is arranged in the second sub-non-display area 22, the second chip 32 is arranged in the fifth sub-non-display area 25, a portion of the signal lines extend in the first direction X and then are imported into the first chip 31, and the other portion of the signal lines 40 extend along the first direction X and then are imported into the second chip 32. Sufficient line space is ensured.

Optionally, the first chip 31 is located on one side of the first sub-bending area 26 away from the first functional area 11, and the second chip 32 is located on one side of the second sub-bending area 27 away from the second functional area 12. The first chip 31 may be bent to the backlight side 72 of the display panel following the second sub-non-display area 22, and the second chip 32 may be bent to the backlight side 72 of the display panel following the fifth sub-non-display area 25. The size of the frame of the display panel is reduced, and the narrow frame design is realized.

Further, in some embodiments, the plurality of the signal lines 40 comprise a first power signal line 42, a second power signal line 43 and data signal lines 41, the first power signal line 42 and the second power signal line 43 are connected to the first chip 31, and the data signal lines 41 are connected to the second chip 32.

Since the number of the data signal lines 41 is large, and the width of the fifth sub-non-display area 25 in the second direction Y is not limited, all the data signal lines 41 are imported into the second chip 32. While the numbers of the first power signal lines 42 and the second power signal lines 43 are small compared with the data signal lines 41, and the width of the second sub-non-display area 22 in the second direction Y is limited, and thus the first power signal lines 42 and the second power signal line 43 are imported into the first chip 31, which facilitates the line arrangement of the second sub-non-display area 22 and ensures that the second sub-non-display area 22 will not block the second functional area 12 after being bent. In addition, the number of the VSR signal lines is also small compared with the data signal lines 41, and thus the VSR signal lines may also be connected to the first chip 31.

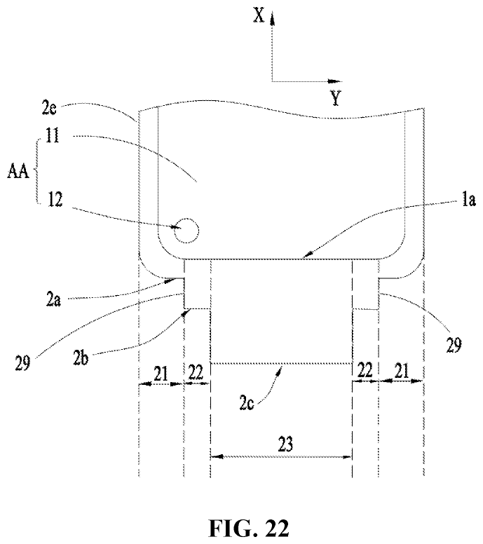

FIG. 22 is yet another partial schematic diagram of a display panel provided by an embodiment of the present application. In the embodiment shown in FIG. 22, a contour edge of an orthographic projection of the non-display area NA in a direction perpendicular to a substrate of the display panel is a step 29, and the first sub-edge 2a and the second sub-edge 2b are parts of an edge of the step 29, respectively.

During the manufacturing process of the display panel, the non-display area NA may be cut from one side of the third edge 2e in the second direction Y and then in the first direction X, to form the step 29, and then the first non-display area 21 and the second sub-non-display area 22 may be obtained.

Optionally, by cutting the non-display area NA from one side of the third edge 2e in the second direction Y and then in the first direction X twice, two steps 29 may be formed, to obtain the first sub-non-display area 21, a second sub-non-display area 22 and a third sub-non-display area 23.

The cutting method of the embodiment is simple and easy to operate. The steps 29 formed by cutting may facilitate the bending of the non-display area NA. The bent non-display area NA will not block the second functional area 12 and will not affect the light transmittance of the second functional area 12.

In other embodiments, both a contour edges of two opposite ends of the display panel in the second direction Y comprise a step 29. The steps at the opposite ends in the second direction Y are symmetrically arranged, which may ensure that the steps 29 have the same stress when they are bent, and no bending cracks will occur.

A second aspect of the present application provides a display apparatus including the display panel described above. Since the display apparatus adopts all the technical solutions of the embodiments described above, it has at least all the beneficial effects brought by the technical solutions of the embodiments described above, which will not be repeated here.

The above are only specific implementations of the present application, and the protection scope of the present application is not limited thereto. Any person skilled in the art may easily conceive of various equivalent modifications or substitutions within the technical scope disclosed in the present, which fall within the protection scope of this application. Therefore, the protection scope of the present application shall be subject to the protection scope of the claims.

What is claimed is:

1. A display panel, comprising:
a display area comprising a first functional area and a second functional area surrounded by the first functional area, wherein a light transmittance of the second functional area is higher than a light transmittance of the first functional area; and
a non-display area located on one side of the first functional area away from the second functional area, wherein the non-display area comprises a first sub-edge and a second sub-edge which form an edge of the display panel, a distance from the first sub-edge to the first functional area is smaller than a distance from the second sub-edge to the first functional area, and the first sub-edge is arranged closer to the second functional area than the second sub-edge.

2. The display panel according to claim 1, wherein the display area has a first edge and a second edge in a first direction which are arranged opposite to and spaced apart from each other, and the first edge and the second edge are located on opposite sides of the second functional area, and the first sub-edge and the second sub-edge are located on a same side of the first edge.

3. The display panel according to claim 2, wherein a distance from the first edge to the second functional area is smaller than a distance from the second edge to the second functional area.

4. The display panel according to claim 2, wherein the non-display area comprises a first sub-non-display area and a second sub-non-display area arranged along the first edge, the first sub-edge is an edge of the first sub-non-display area, and the second sub-edge is an edge of the second sub-non-display area.

5. The display panel according to claim 4, wherein the non-display area further comprises a third sub-non-display area located on one side of the second sub-non-display area away from the first sub-non-display area, the third sub-non-display area comprises a third sub-edge forming the edge of the display panel, and the distance from the second sub-edge to the first functional area is smaller than a distance from the third sub-edge to the first functional area.

6. The display panel according to claim 4, wherein the non-display area further comprises a first sub-bending area, and at least part of the first sub-bending area is located within an area of the second sub-non-display area.

7. The display panel according to claim 6, wherein the non-display area comprises a third edge and a fourth edge arranged opposite to each other in a second direction, the first direction and the second direction are perpendicular to each other, the third edge is arranged close to the second functional area, the second functional area is formed with a first end and a second end in the first direction, and the first end is arranged close to the first edge; and in the first direction, a distance from the second sub-edge to the first sub-bending area is smaller than or equal to a distance from the first sub-bending area to the first end.

8. The display panel according to claim 4, wherein the non-display area comprises a third edge and a fourth edge arranged opposite to each other in a second direction, and the first direction and the second direction are perpendicular to each other, the third edge is arranged close to the second functional area, the second functional area is formed with a third end and a fourth end in the second direction, and the third end is arranged close to the third edge; and in the second direction, a distance from the third edge to the second sub-non-display area is greater than or equal to a distance from the third edge to the fourth end.

9. The display panel according to claim 4, wherein the non-display area further comprises a binding area, and the binding area is located within an area of the second sub-non-display area.

10. The display panel according to claim 4, wherein the first sub-edge and the second sub-edge extend in a second direction respectively, and the first direction and the second direction are perpendicular to each other.

11. The display panel according to claim 4, wherein the first sub-edge and/or the second sub-edge is inclined in a direction away from the first functional area, with respect to a second direction, and the first direction and the second direction are perpendicular to each other.

12. The display panel according to claim 4, wherein the non-display area further comprises a fourth sub-non-display area located on one side of the second edge, and the first sub-non-display area is arranged closer to the second functional area than the fourth sub-non-display area.

13. The display panel according to claim 12, wherein the non-display area further comprises a fifth sub-non-display area located on one side of the second edge, and a width of the fourth sub-non-display area in the first direction is smaller than a width of the fifth sub-non-display area in the first direction.

14. The display panel according to claim 13, wherein the display panel further comprises a first chip, a second chip and a plurality of signal lines extending in the first direction, the first chip is arranged in the second sub-non-display area, the second chip is arranged in the fifth sub-non-display area, a portion of the signal lines are connected to the first chip, and the other portion of the signal lines are connected to the second chip.

15. The display panel according to claim 14, wherein the plurality of the signal lines comprise a first power signal line, a second power signal line and a data signal line, the first power signal line and the second power signal line are connected to the first chip, and the data signal line is connected to the second chip.

16. The display panel according to claim 1, wherein a contour edge of an orthographic projection of the non-display area in a direction perpendicular to a substrate of the display panel is step, and the first sub-edge and the second sub-edge are parts of an edge of the step, respectively.

17. The display panel according to claim 16, wherein both a contour edges of two opposite ends of the display panel in the second direction comprise the step.

18. A display apparatus comprising the display panel according to claim 1.
